(19) United States
(12) Patent Application Publication
(10) Pub. No.: US 2026/0279731 A1
(43) Pub. Date: Sep. 17, 2026

(54) POWER SUPPLY DEVICE AND PLASMA PROCESSING APPARATUS

(71) Applicant: ASENDIA Co., Ltd., Pyeongtaek-si (KR)

(72) Inventors: In Kyu KIM, Pyeongtaek-si (KR); Jin Young KIM, Yongin-si (KR)

(21) Appl. No.: 19/561,352

(22) Filed: Mar. 9, 2026

(30) Foreign Application Priority Data
Mar. 11, 2025 (KR) 10-2025-0031377

(51) Int. Cl. H01J 37/32

(52) U.S. Cl. CPC H01J 37/32183; H01J 37/32935

(57) ABSTRACT

A power supply device, which supplies power to a plurality of loads, in accordance with an embodiment of the present disclosure includes a reference signal generation unit configured to generate a reference signal, a plurality of signal generation units configured to generate power signals input into the plurality of loads, and a plurality of matching units, each of which is configured to receive the reference signal from the reference signal generation unit, and which are configured to transmit the power signals generated in the plurality of signal generation units to the plurality of loads, respectively. Each of the matching units is configured to compare a phase of the input reference signal with a phase of the power signal generated from each of the signal generation units so as to output a synchronization signal having a set phase, and the signal generation unit is configured to receive the synchronization signal from the matching unit so as to generate a power signal having a set phase.

### CROSS-REFERENCE TO RELATED APPLICATION

This application claims priority to Korean Patent Application No. 10-2025-0031377 filed on Mar. 11, 2025 and all the benefits accruing therefrom under 35 U.S.C. § 119, the contents of which are incorporated by reference in their entirety.

### BACKGROUND

The present disclosure relates to a power supply device and a plasma processing apparatus, and more particularly, to a power supply device that supplies power to a plurality of loads and a plasma processing apparatus.

A plasma processing apparatus for manufacturing a semiconductor includes a processing device capable of performing various processing using plasma. The processing device is used variously in etching, deposition, cleaning, and ashing processes, etc., and receives power signals from a power supply device to generate and maintain plasma in a reaction space.

The power supply device may supply power to a plurality of loads included in the processing device to provide a uniform density of plasma or improve productivity of a product. For example, the processing device may include a plurality of divided electrodes, and the power signals may be supplied to the divided electrodes, respectively. In addition, the processing device has a plurality of reaction spaces for processing a plurality of substrates, respectively, and the power signals may be supplied to the electrodes provided in the divided plurality of reaction spaces, respectively.

Thus, when supplying the power signals to the plurality of loads, the supplied power signals have to have the same phase. If the power signals with different phases are supplied to the processing device, noise may be generated due to mutual interference, i.e., cross-talk, making it impossible to stably generate plasma. Thus, there is a need for development of the power supply device that supplies the power signals having the same phase to the plurality of loads to generate stable plasma.

### PRIOR ART DOCUMENT

### Patent Document

(Patent Document 1) KR 10-2077512 B1

### SUMMARY

The present disclosure provides a power supply device capable of generating multi-channel power signals having the same phase, and a plasma processing apparatus.

In accordance with an exemplary embodiment, a power supply device, which supplies power to a plurality of loads, includes: a reference signal generation unit configured to generate a reference signal; a plurality of signal generation units configured to generate power signals input into the plurality of loads; and a plurality of matching units, each of which is configured to receive the reference signal from the reference signal generation unit, and which are configured to transmit the power signals generated in the plurality of signal generation units to the plurality of loads, respectively, wherein each of the matching units is configured to compare a phase of the input reference signal with a phase of the power signal generated from each of the signal generation units so as to output a synchronization signal having a set phase, and the signal generation unit is configured to receive the synchronization signal from the matching unit so as to generate a power signal having a set phase.

The matching unit may include: a detector configured to receive the power signal from the signal generation unit so as to detect the phase; a matcher configured to match impedances between the detector and each of the loads; and a synchronization signal generator configured to receive the reference signal from the reference signal generation unit and receive phase information of the power signal from the detector so as to generate the synchronization signal having a set phase.

The synchronization signal generator may include: a digital signal converter configured to convert the phase information of the power signal received from the detector into a digital signal; a calculator configured to receive the reference signal from the reference signal generation unit and receive the digital signal from the digital signal converter so as to calculate a phase difference between the reference signal and the power signal; a digital synchronization signal generator configured to receive information about the phase difference from the calculator so as to generate a digital synchronization signal having a set phase; and an analog signal converter configured to receive the digital synchronization signal from the digital synchronization signal generator so as to convert the digital synchronization signal into an analog synchronization signal.

The digital synchronization signal generator may be configured to generate a digital synchronization signal having the same phase as the reference signal.

The digital synchronization signal generator may be configured to generate a digital synchronization signal having a set phase difference with respect to the reference signal.

In accordance with another exemplary embodiment, a plasma processing apparatus includes: any one power supply device described above; and a processing device having a plurality of reaction spaces and connected to the power supply device to generate plasma in each of the plurality of reaction spaces by receiving each of the power signals transmitted from the plurality of matching units.

The processing device may include a chamber configured to provide the plurality of reaction spaces.

### BRIEF DESCRIPTION OF THE DRAWINGS

Exemplary embodiments can be understood in more detail from the following description taken in conjunction with the accompanying drawings, in which:

FIG. 1 is a schematic view illustrating a plasma processing apparatus including a power supply device in accordance with an exemplary embodiment; and

FIG. 2 is a schematic view illustrating a structure of a matching unit included in the power supply device in accordance with an exemplary embodiment.

### DETAILED DESCRIPTION OF EMBODIMENTS

Hereinafter, exemplary embodiments of the present inventive concept will be described in detail with reference to the accompanying drawings. The present inventive concept may, however, be embodied in different forms and should not be construed as limited to the embodiments set forth herein. Rather, these embodiments are provided so that the present inventive concept will be thorough and complete, and will fully convey the scope of the present inventive concept to those skilled in the art. In order to explain the present inventive concept in detail, the drawings may be exaggerated, and the same symbols in the drawings refer to the same elements.

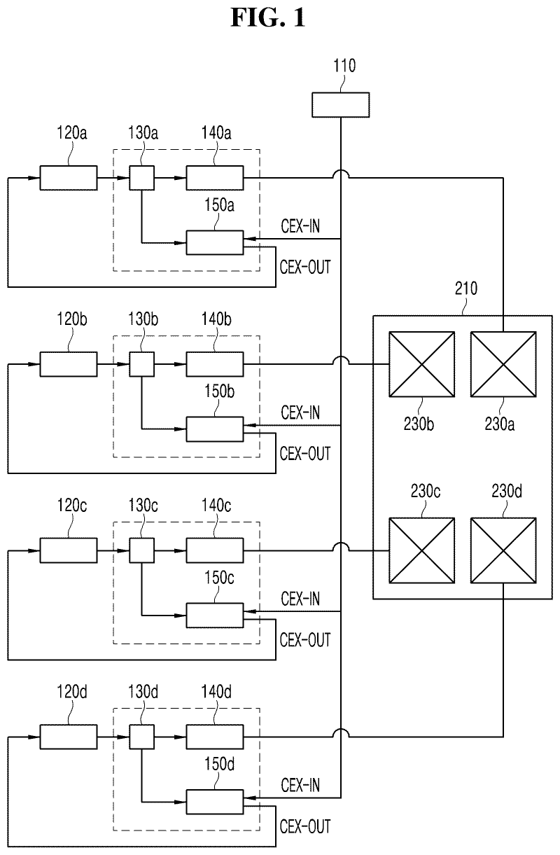

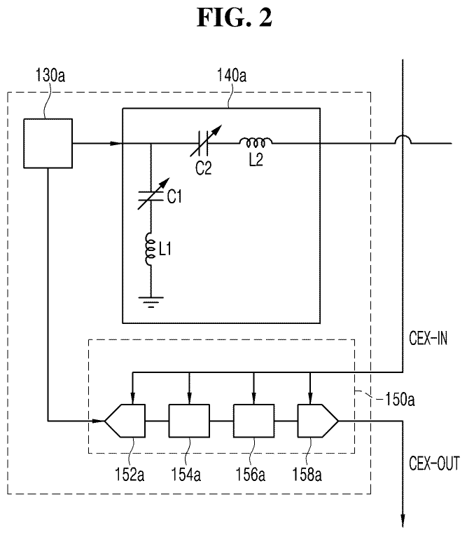

FIG. 1 is a schematic view illustrating a plasma processing apparatus including a power supply device in accordance with an exemplary embodiment, and FIG. 2 is a schematic view illustrating a structure of a matching unit included in the power supply device in accordance with an exemplary embodiment.

Referring to FIGS. 1 and 2, a plasma processing apparatus in accordance with an exemplary embodiment of the present disclosure includes a power supply device that supplies power to a plurality of loads to generate plasma and a processing device having a plurality of reaction spaces and connected to the power supply device to receive the power signal from the power supply device so as to generate plasma in each of the plurality of reaction spaces.

Hereinafter, an example in which the power signal is transmitted to four loads 230a, 230b, 230c, and 230d, i.e., four channels will be described. However, the number of loads and the number of channels for supplying the power signals to the loads are not limited thereto, and may be variously changed. In addition, in describing the present disclosure, the term “connection” means both wired connection and wireless connection for the transmission of the electrical signals.

The power supply device may be a device that supplies power to the plurality of loads 230a, 230b, 230c, and 230d and may include a reference signal generation unit 110 capable of generating a reference signal, a plurality of signal generation units 120a, 120b, 120c, and 120d capable of generating power signals to be input to the plurality of loads 230a, 230b, 230c, and 230d, and a plurality of matching units capable of receiving the reference signal from the reference signal generation unit 110 to transmit the power signals generated by the plurality of signal generation units 120a, 120b, 120c, and 120d to the plurality of loads 230a, 230b, 230c, and 230d. Here, each matching unit may compare a phase of the input reference signal with the phase of the power signal generated from each of the signal generation units 120a, 120b, 120c, and 120d to output a synchronization signal having a set phase, and each of the signal generation units 120a, 120b, 120c, and 120d may receive the synchronization signal from the matching unit to generate a power signal having a set phase.

The reference signal generation unit 110 may generate a plurality of reference signals that are respectively supplied to the plurality of matching units. Here, the reference signal refers to a signal that serves as a basis for matching the phases of the power signals, which are supplied to the plurality of loads 230a, 230b, 230c, and 230d, respectively. All the plurality of reference signals generated by the reference signal generation unit 110 may have the same frequency and phase.

The plurality of signal generation units 120a, 120b, 120c, and 120d may generate the power signals to be input to the plurality of loads 230a, 230b, 230c, and 230d, respectively. The plurality of signal generation units 120a, 120b, 120c, and 120d may be provided in four numbers, for example, and may receive a plurality of synchronization signals output from the plurality of matching units, respectively. The plurality of signal generation units 120a, 120b, 120c, and 120d may initially generate power signals having set frequencies and phases, respectively. Thereafter, when receiving the plurality of synchronization signals from the plurality of matching units, the plurality of signal generation units may amplify the received synchronization signals to generate power signals. For example, the plurality of signal generation units 120a, 120b, 120c, and 120d generate a plurality of power signals supplied to the processing device by maintaining a frequency and phase of the synchronization signal and changing an amplitude of the synchronization signal.

The plurality of matching units may receive the reference signals from the reference signal generation unit 110, respectively, and may transmit power signals generated by the plurality of signal generation units 120a, 120b, 120c, and 120d to the plurality of loads 230a, 230b, 230c, and 230d, respectively.

Here, each matching unit may include detectors 130a, 130b, 130c, and 130d capable of detecting a phase by receiving the power signal from each of the signal generation units 120a, 120b, 120c, and 120d, matchers 140a, 140b, 140c, and 140d capable of matching impedances between each of the detectors 130a, 130b, 130c, and 130d and each of the loads 230a, 230b, 230c, and 230d, and synchronization signal generators 150a, 150b, 150c, and 150d capable of receiving the reference signal from the reference signal generation unit 110 and receiving phase information of the power signal from each of the detectors 130a, 130b, 130c, and 130d to generate a synchronization signal having a set phase.

The detectors 130a, 130b, 130c, and 130d are provided at output terminals of the signal generation units 120a, 120b, 120c, and 120d, respectively, and may receive the power signals from the signal generation units 120a, 120b, 120c, and 120d to detect phases. The detectors 130a, 130b, 130c, and 130d may also further detect amplitudes, frequencies, power values, etc., of the power signals output from the signal generation units 120a, 120b, 120c, and 120d.

The matchers 140a, 140b, 140c, and 140d may match impedances between the signal generation units 120a, 120b, 120c, and 120d and the loads 230a, 230b, 230c, and 230d, respectively. That is, the matchers 140a, 140b, 140c, and 140d may detect reflected waves transmitted from the loads 230a, 230b, 230c, and 230d to the signal generation units 120a, 120b, 120c, and 120d, and may match the impedances so that the reflected waves are minimized. As illustrated in FIG. 2, the matchers 140a, 140b, 140c, and 140d may include standard L-type matching circuits in which two variable elements are connected in series and parallel. Here, the matching circuits 140a, 140b, 140c, and 140d may change the impedance of the variable element, and more specifically, capacitive reactance or inductive reactance to match the impedance. The impedance matching through the matching circuits is a well-known technique, and thus, detailed descriptions thereof will be omitted. In addition, although FIG. 2 illustrates an embodiment in which the impedances are matched by changing the capacitances of the parallel variable capacitor C1 and the serial variable capacitor C2, the impedances may also be matched by changing the inductances of the parallel inductor L1 and the serial inductor L2. In addition, the matching circuits 140a, 140b, 140c, and 140d may include various matching circuits capable of matching the impedances between the signal generation unit 110 and the load in addition to the standard L-type matching circuits.

The synchronization signal generators 150a, 150b, 150c, and 150d may receive the reference signal from the reference signal generation unit 110 and may receive the phase information of the power signal from each of the detectors 130a, 130b, 130c, and 130d to generate a synchronization signal having a set phase.

Here, the synchronization signal generators 150a, 150b, 150c, and 150d may include digital signal converters 152a, 152b, 152c, and 152d capable of converting the phase information of the power signal received from each of the detectors 130a, 130b, 130c, and 130d into a digital signal, calculators 154a, 154b, 154c, and 154d which receive the reference signal from the reference signal generation unit 110 and receives the digital signal from each of the digital signal converters 152a, 152b, 152c, and 152d to calculate a phase difference between the reference signal and the power signal, digital synchronization signal generators 156a, 156b, 156c, and 156d capable of receiving information about the phase difference from each of the calculators 154a, 154b, 154c, and 154d to generate a digital synchronization signal having a set phase, and analog signal converters 158a, 158b, 158c, and 158d capable of receiving the digital synchronization signal from each of the digital synchronization signal generators 156a, 156b, 156c, and 156d to convert the digital synchronization signal into an analog synchronization signal.

The digital signal converters 152a, 152b, 152c, and 152d may convert the phase information of the power signals received from the detectors 130a, 130b, 130c, and 130d into digital signals. The digital signal converters 152a, 152b, 152c, and 152d may include an analog-to-digital converters (ADC) that converts an analog signal into a digital signal.

The calculators 154a, 154b, 154c, and 154d may receive the reference signal from the reference signal generation unit 110 and receive the digital signal from each of the digital signal converters 152a, 152b, 152c, and 152d to calculate the phase difference between the reference signal and the power signal. That is, the calculators 154a, 154b, 154c, and 154d may receive the reference signal from the reference signal generation unit 110 to detect the phase of the reference signal, may receive the digital signal from each of the digital signal converters 152a, 152b, 152c, and 152d to detect the phase of the power signal, and may compare the detected phase of the reference signal with the phase of the power signal to calculate the phase difference between the reference signal and the power signal.

The digital synchronization signal generators 156a, 156b, 156c, and 156d may receive information about the phase difference from the calculators 154a, 154b, 154c, and 154d to generate digital synchronization signals having set phases. The digital synchronization signal generators 156a, 156b, 156c, and 156d may include direct digital synthesis cores (DDS cores), and the direct digital synthesis cores (DDS cores) may generate digital synchronization signals having frequencies and phases, which are set by a direct digital synthesis (DDS) method. Here, each of the digital synchronization signal generators 156a, 156b, 156c, and 156d may generate a digital synchronization signal having the same phase as the reference signal or may generate a digital synchronization signal having a set phase difference with respect to the reference signal.

The analog signal converters 158a, 158b, 158c, and 158d may receive the digital synchronization signals from the digital synchronization signal generators 156a, 156b, 156c, and 156d and convert the digital synchronization signals into analog synchronization signals. The analog signal converters 158a, 158b, 158c, and 158d may include digital-to-analog converters (DACs) that convert digital signals into analog signals. All the analog synchronization signals output from the analog signal converters 158a, 158b, 158c, and 158d may have the same phase, and the signal generation units 120a, 120b, 120c, and 120d may receive synchronization signals from the analog signal converters 158a, 158b, 158c, and 158d to generate power signals having the same phase as the synchronization signals, respectively.

The processing device may receive a power signal to generate plasma in the reaction space. Here, the processing device may have a plurality of reaction spaces and may be connected to the power supply device to receive a power signal from the power supply device to generate plasma in each of the plurality of reaction spaces. The processing device may include a chamber 210 and loads 230a, 230b, 230c, and 230d, which are connected to a plurality of matchers 140a, 140b, 140c, and 140d, respectively. The loads 230a, 230b, 230c, and 230d may include electrodes provided in the plurality of reaction spaces, for example, gas supply units. In addition, although not shown, the processing device may further include a substrate support.

The chamber 210 may provide a predetermined reaction space to maintain sealing of the reaction space. The chamber 210 may include a body including an approximately circular or square-shape plane and a sidewall extending upward from the plane and having a predetermined reaction space and a lid 14 having an approximately circular or square shape and disposed on the body to seal the chamber. However, the chamber 210 is not limited thereto and may be manufactured in various shapes corresponding to the shape of the substrate.

Here, a plurality of reaction spaces may be provided. That is, the chamber 210 may include a plurality of reactors that provide reaction spaces for processing a plurality of substrates, respectively, to improving productivity. Although the drawing illustrates an example in which four reaction spaces are provided, it is of course possible to provide a different number of reaction spaces.

A substrate S provided into the chamber 210 for plasma processing may be seated on the substrate support. Here, the substrate may include various substrates such as a wafer, a glass substrate, or a plastic substrate. The substrate support may act as a lower electrode when grounded to form plasma in the reaction space. The substrate support may be divided into a plurality of portions to support a large-area substrate or may be provided in plurality so as to be installed in the reaction spaces when the chamber 210 provides the plurality of reaction spaces.

The gas supply unit may correspond to the above-described loads 230a, 230b, 230c, and 230d. The gas supply unit may be provided, for example, at an upper side inside the chamber 210 and may inject a process gas into the reaction space. For example, the gas supply unit may include a shower head having an upper side connected to a gas supply line (not shown) and a lower side in which a plurality of fine injection holes for injecting the process gas onto the substrate are defined. When generating plasma in the reaction space, a power signal may be input to the gas supply unit so that the gas supply unit acts as an upper electrode. The gas supply unit may be provided to be divided into a plurality of portions so as to inject the process gas onto the large-area substrate or may be provided in plurality so as to be installed facing the substrate support in each reaction space when the chamber 210 provides the plurality of reaction spaces.

When the electrode is divided into a plurality of portions in the processing device, or when a plurality of reaction spaces are provided so that electrodes are disposed in the reaction space, respectively, the power signals supplied to the gas supply unit have to have the same phase to stably generate plasma. In an embodiment of the present disclosure, the synchronization signals having the same phase may be generated in the plurality of matching units, and the generated synchronization signals may be amplified to generate the power signals having the same phase, thereby minimizing an interference between the power signals.

As described above, in accordance with the exemplary embodiment of the present disclosure, the phase of the reference signal and the phase of the power signal may be compared to output the synchronization signal having the set phase and adjust the phase of the power signal so that the power signal has the same phase as the synchronization signal, thereby generating the multi-channel power signals having the same phase.

Furthermore, when processing the large-area substrate or processing the plurality of substrates at the same time, the plasma may be stably generated to allow for the uniform processing of the substrates.

In accordance with the exemplary embodiment of the present disclosure, the phase of the reference signal and the phase of the power signal may be compared to output the synchronization signal having the set phase and adjust the phase of the power signal so that the power signal has the same phase as the synchronization signal, thereby generating the multi-channel power signals having the same phase.

Furthermore, when processing the large-area substrate or processing the plurality of substrates at the same time, the plasma may be stably generated to allow for the uniform processing of the substrates.

Although the specific embodiments are described and illustrated by using specific terms, the terms are merely examples for clearly explaining the embodiments, and thus, it is obvious to those skilled in the art that the embodiments and technical terms can be carried out in other specific forms and changes without changing the technical idea or essential features. Therefore, it should be understood that simple modifications in accordance with the embodiments of the present inventive concept may belong to the technical spirit of the present inventive concept.

### DESCRIPTION OF THE SYMBOLS

| | |
|---|---|
| 110: Reference signal generation unit | 120: Signal generation unit |
| 130: Detector | 140: Matcher |
| 150: Synchronization signal generator | 210: Chamber |
| 230: Load | |

1. A power supply device, which supplies power to a plurality of loads, the power supply device comprising:
a reference signal generation unit configured to generate a reference signal;
a plurality of signal generation units configured to generate power signals input into the plurality of loads; and
a plurality of matching units, each of which is configured to receive the reference signal from the reference signal generation unit, and which are configured to transmit the power signals generated in the plurality of signal generation units to the plurality of loads, respectively,
wherein each of the matching units is configured to compare a phase of the input reference signal with a phase of the power signal generated from each of the signal generation units so as to output a synchronization signal having a set phase, and
the signal generation unit is configured to receive the synchronization signal from the matching unit so as to generate a power signal having a set phase.

2. The power supply device of claim 1, wherein the matching unit comprises:
a detector configured to receive the power signal from the signal generation unit so as to detect the phase;
a matcher configured to match impedances between the detector and each of the loads; and
a synchronization signal generator configured to receive the reference signal from the reference signal generation unit and receive phase information of the power signal from the detector so as to generate the synchronization signal having a set phase.

3. The power supply device of claim 2, wherein the synchronization signal generator comprises:
a digital signal converter configured to convert the phase information of the power signal received from the detector into a digital signal;
a calculator configured to receive the reference signal from the reference signal generation unit and receive the digital signal from the digital signal converter so as to calculate a phase difference between the reference signal and the power signal;
a digital synchronization signal generator configured to receive information about the phase difference from the calculator so as to generate a digital synchronization signal having a set phase; and
an analog signal converter configured to receive the digital synchronization signal from the digital synchronization signal generator so as to convert the digital synchronization signal into an analog synchronization signal.

4. The power supply device of claim 3, wherein the digital synchronization signal generator is configured to generate a digital synchronization signal having the same phase as the reference signal.

5. The power supply device of claim 3, wherein the digital synchronization signal generator is configured to generate a digital synchronization signal having a set phase difference with respect to the reference signal.

6. A plasma processing apparatus comprising:
the power supply device of claim 1; and
a processing device having a plurality of reaction spaces and connected to the power supply device to generate plasma in each of the plurality of reaction spaces by receiving each of the power signals transmitted from the plurality of matching units.

7. The plasma processing apparatus of claim 6, wherein the processing device comprises a chamber configured to provide the plurality of reaction spaces.
